(19) United States
(12) Patent Application Publication
(10) Pub. No.: US 2015/0351293 A1
(43) Pub. Date: Dec. 3, 2015

(54) TOUCH DISPLAY DEVICE

(71) Applicant: BOE Technology Group Co., Ltd, Beijing (CN)

(72) Inventor: Xinli Ma, Beijing (CN)

(21) Appl. No.: 14/500,579

(22) Filed: Sep. 29, 2014

(30) Foreign Application Priority Data
May 27, 2014 (CN) 201410228224.8

(51) Int. Cl. H05K 9/00; G06F 3/041

(52) U.S. Cl. CPC H05K 9/0081; G06F 3/0412; H05K 9/0094

(57) ABSTRACT

The general inventive concepts relate to a touch display device for reducing interference from electromagnetic waves generated outside and inside to the touch film so as to improve the touch effect of the touch film. The touch display device comprises a display module, a touch substrate and a touch film located on the touch substrate, wherein the touch display device further comprises a shielding structure located on a first surface the touch film, the shielding structure capable of shielding interference from electromagnetic waves to the touch film.

### RELATED APPLICATIONS

The present application claims the benefit of Chinese Patent Application No. 201410228224.8, filed May 27, 2014, the entire disclosure of which is incorporated herein by reference.

### FIELD

The general inventive concepts relate to the field of display technology, and more particularly to a touch display device.

### BACKGROUND

Conventional displays in the prior art combine the specular function and the display function together. Currently, the approach to carry out the touch-control function via the specular display mainly includes infrared touch, acoustic wave touch or using a touch film for sensing input. While using a touch film for touch can make the appearance of the display more elegant. The structure of the touch film in the prior art is a nanostructure generally, while in the specific process of carrying out the touch, it may be easily interfered by external electromagnetic waves when using a touch film in a nanostructure for carrying out the touch, thereby influencing the touch effect of the touch film.

In order to reduce interference from external electromagnetic waves, the prior art usually adopts the method of keeping enough spacing between the touch film and the display module. Although such a design can provide benefits, it may still allow interference to the touch-control function of the touch film if the electromagnetic waves from the display module are abnormal. In addition, the spacing required for adequate shielding of between the touch film and the display module may make the thickness of the whole system with the specular display module greater, thereby making the device undesirably bulky.

### SUMMARY

The present disclosure provides a display device. The display device may avoid, or otherwise alleviate, one or more of the drawbacks of conventional display devices.

The touch display device provided by the present disclosure is used for reducing interference from external electromagnetic waves to the touch film so as to improve the touch effect of the touch film while maintaining a relatively thin profile.

According to an embodiment of the present disclosure, a touch display device is provided, comprising a display module, a touch substrate and a touch film located on the touch substrate, wherein the touch display device further comprises a shielding structure located on a first surface of the touch film. Wherein the shielding structure is capable of shielding interference from electromagnetic waves to the touch film.

According to certain embodiments, the touch display device uses a shielding structure located on a first surface of the touch film to shield interference from electromagnetic waves to the touch film. The shielding reduces interference of external electromagnetic waves and electromagnetic waves from internal components (such as the display module) to the touch film. As a result the touch effect of the touch film is enhanced.

In certain embodiments, the touch substrate of the touch display device is plated with a specular reflection film layer.

In certain embodiments, the specular reflection film may be a monofilm or a complex film selected from silicon oxide, titanium oxide, aluminum oxide or other similar monofilm or complex film.

In certain embodiments, the shielding structure comprises a substrate and a shielding layer located on the substrate. When there is an external electric field, the charges in the shielding layer (such as a metal layer) can compensate electrically and the internal electric field thereof becomes zero after redistribution. As a result, the touch film is effectively shielded from electromagnetic interference from the external electromagnetic waves and its functioning is preserved.

In certain embodiments, the shielding structure is located between the display module and the touch substrate. When positioned between the display module and the touch substrate the shielding structure may more effectively shield the interference from the electromagnetic waves generated by the display module from reaching the touch film.

In certain embodiments, the shielding structure comprises a transparent substrate and a transparent shielding layer located on the transparent substrate. Such a transparent structure has the added benefit of minimizing interference with the actual display.

In certain embodiments, the distance between the shielding layer and the display module may be 0 to 10 mm. In addition, the distance between the shielding layer and the touch substrate may be 0.1 to 5 mm. The above two distance settings are simple and practicable in actual applications and may not result in too great thickness of the whole system with the specular display module, thereby achieving the effects while maintaining a relatively thin profile.

In certain embodiments, the shielding layer may be a transparent conducting layer or grid-shaped metal lines. When the shielding layer is a transparent conducting layer, the shielding layer will not influence the display effect of the display module while shielding the interference from the electromagnetic waves. When the shielding layer is grid-shaped metal lines, since the grid-shaped metal lines are hollow, the shielding layer in such a case also will not influence the display effect of the display module while shielding the interference from the electromagnetic waves.

In certain embodiments, the transparent conducting layer is an ITO transparent conducting layer or a metal layer. These materials facilitate actual application and fabrication of the transparent conducting layer while ensuring the shielding effect.

In certain embodiments, the grid-shaped metal lines are arranged to correspond in position with the non-display area of the display module, so as not to influence the display effect of the touch display device.

In certain embodiments, the grid-shaped metal lines are arranged to correspond in position with the display area and the non-display area of the display module, wherein the grid-shaped metal lines arranged to correspond in position with the non-display area are more concentrated than the grid-shaped metal lines arranged to correspond in position with the display area. One benefit of the grid-shaped metal lines, the lines are distributed so as to minimize any impact to the transmittance of the panel. In other words, the metal line may overlap with the black matrix to as great an extent as necessary, while taking into account the alignment deviation, etc. Such an arrangement enables more flexibility in the fabrication of the grid-shaped metal line.

In an embodiment of a touch display device according to the present disclosure, the width of the grid-shaped metal line may be 5 to 100 microns, and the spacing between the grid-shaped metal lines may be 0.05 to 10 mm. In this way, it makes the actual fabricating process of the grid-shaped metal line more simple, convenient and practicable while ensuring the shielding effect.

### BRIEF DESCRIPTION OF DRAWINGS

Several technical aspects of the present disclosure will be described in more detail below with reference to the accompanying drawings in order for those skilled in the art to be able to carry out the present disclosure. The present disclosure may, however, be embodied in many different forms and should not be construed as limited to the exemplary embodiments set forth herein. In particular, the general inventive concepts are not intended to be limited by the various illustrative embodiments disclosed herein.

FIG. 1 shows a touch display device according to the first embodiment of the present disclosure;

FIG. 2 shows a touch display device according to the second embodiment of the present disclosure;

FIG. 3 shows a touch display device according to the third embodiment of the present disclosure;

FIG. 4 shows a touch display device according to the fourth embodiment of the present disclosure;

FIG. 5 shows a touch display device according to the fifth embodiment of the present disclosure;

FIG. 6 shows a touch display device according to the sixth embodiment of the present disclosure; and

FIG. 7 shows the planar structure of the shielding layer in the touch display device according to an embodiment of the present disclosure, wherein the shielding layer is grid-shaped metal lines.

It should be noted that the drawings are illustrative only and should not be understood as providing any limitation to the claims.

### DETAILED DESCRIPTION OF EMBODIMENTS

The present invention and associated general inventive concepts will be further described hereinafter in detail with reference to the accompanying drawings and various exemplary embodiments. One of ordinary skill in the art will appreciate that these exemplary embodiments only constitute a fraction of the possible embodiments encompassed by the present invention and associated general inventive concepts. As such, the scope of the present disclosure is by no means limited to the exemplary embodiments set forth herein.

Accordingly, the touch display device according to the general inventive concepts will be described in greater detail in conjunction with the drawings.

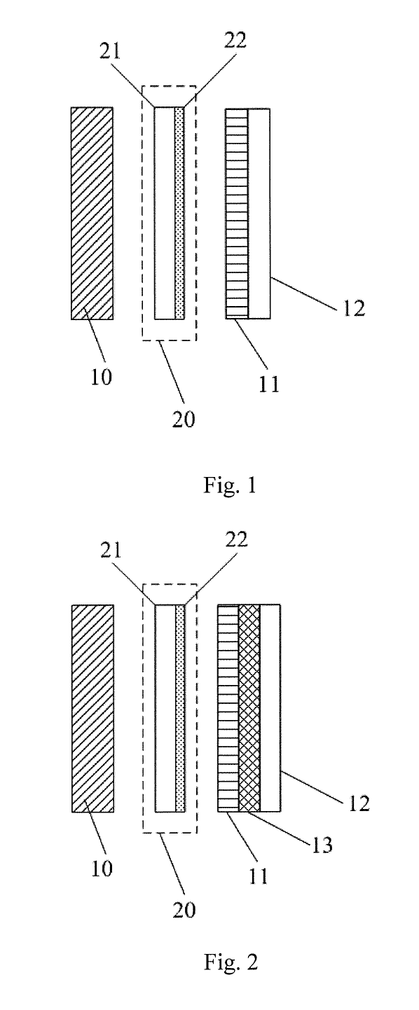

FIG. 1 shows a touch display device according to the first embodiment of the present disclosure. The touch display device as shown in FIG. 1 comprises a display module 10, a touch substrate 12 and a touch film 11 located on the touch substrate 12, and a shielding structure 20 located on a first surface of the touch film 11. The shielding structure 20 capable of shielding interference from electromagnetic waves to the touch film 11.

As shown in FIG. 1, the shielding structure 20 may comprise a substrate 21 and a shielding layer 22 located on the substrate 21. The substrate 21 comprised by the shielding structure 20 may be a transparent substrate, for example, the substrate 21 may be a glass substrate. Moreover, in order to maintain a relatively thin profile for the touch display device, the glass substrate may be an ultrathin glass substrate. The shielding layer 22 comprised by the shielding structure 20 may be a transparent shielding layer. As shown in FIG. 1, the shielding structure 20 is located between the display module 10 and the touch substrate 12 and is capable of shielding interference from electromagnetic waves generated by the display module 10 to the touch film 11. In addition, the touch substrate 12 may be also a glass substrate. In order to maintain an overall thin profile for the touch display device, the glass substrate may be an ultrathin glass substrate.

FIG. 2 shows a touch display device according to the second embodiment of the present disclosure. Similar to FIG. 1, the touch display device as shown in FIG. 2 comprises a display module 10, a touch substrate 12, a touch film 11 located on the touch substrate 12 and a shielding structure 20 located on a first surface of the touch film 11, the shielding structure 20 being used for shielding interference from electromagnetic waves to the touch film 11. In contrast to FIG. 1, in FIG. 2, the touch substrate 12 is plated with a specular reflection film layer 13, such that the specular display function of the touch display device can be carried out more efficiently. The specular reflection film 13 can be made of non-metallic materials with relatively large resistivity. For example, the specular reflection film layer 13 may be a monofilm or a complex film of silicon oxide (SiO₂) or titanium oxide (TiO₂) or aluminum oxide (Al₂O₃).

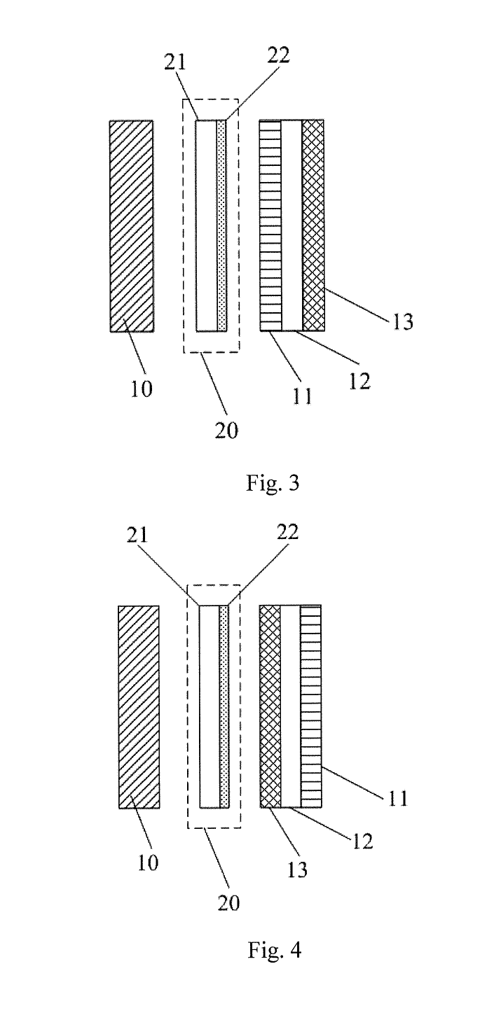

FIG. 3 shows a touch display device according to the third embodiment of the present disclosure. The touch display device as shown in FIG. 3 differs from FIG. 2 in that the specular reflection film layer 13 is fabricated on a surface of the touch substrate 12 away from the touch film 11.

In FIG. 3, the shielding structure 20, similar to FIG. 1, is located between the display module 10 and the touch substrate 12. However, the shielding structure 20 may also be fabricated at a side of the touch substrate 12 away from the display module 10, i.e., being directly fabricated on the specular reflection film layer 13. In such a case, the shielding structure 20 may require no substrate 21, while directly integrating the shielding layer 22 and the specular reflection film layer 13 together as a metal film layer. Because the touch film 11 is on the exterior, using such metal film layer will not influence its ability to receive input from a user via, for example, induction from human fingers and the like.

FIG. 4 shows a touch display device according to the fourth embodiment of the present disclosure. As shown in FIG. 4, the touch film 11 may also be arranged on a surface of the touch substrate 12 plated with the specular reflection film layer 13 away from the display module 10. The specific embodiments of the present disclosure do not define the positions of the specular reflection film layer 13 and the touch film 11 specifically.

One difference between the touch display device structures as shown in FIG. 3 and FIG. 4 is as follows. In the embodiment as shown in FIG. 3, the specular reflection film layer 13 is at the exterior. In such a case, the specular reflection film layer 13 has to use a non-metal plating film, because the metal plating film may shield the electric field of the human fingers and then the touch film accurately receive input from a user. However, the specular effect may actually be better. Whereas in the embodiment as shown in FIG. 4, the touch film 11 is at the exterior of the machine, and thus the specular reflection film layer 13 may use a metal film or a non-metal film, but there is a corresponding tradeoff with the specular effect.

In the touch display device according to the first to the fourth embodiments of the present disclosure as shown in FIGS. 1-4, the shielding layer 22 in the shielding structure 20 is located on a surface of the substrate 21 facing the touch substrate 12.

Furthermore, as shown in FIGS. 1-4, in certain embodiments, the distance between the shielding layer 22 and the display module 10 may be 0 to 10 mm, and can be adjusted between these values based on a variety of factors. The distance between the shielding layer 22 and the touch substrate 12 may be 0.1 to 5 mm, similarly, the distance between the shield layer 22 and the touch substrate 12 can be adjusted based on the requirement of actual production. The ranges of the distances between the shielding layer 22 and the display module 10 as well as the touch substrate 12 discussed above can reduce the thickness of the whole machine effectively and help to achieve a desired thin profile while ensuring the shielding layer 22 provides an adequate shield of the electromagnetic interference from the display module 10 or the outside.

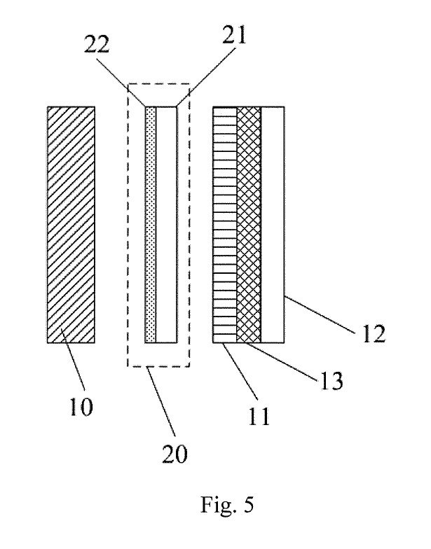

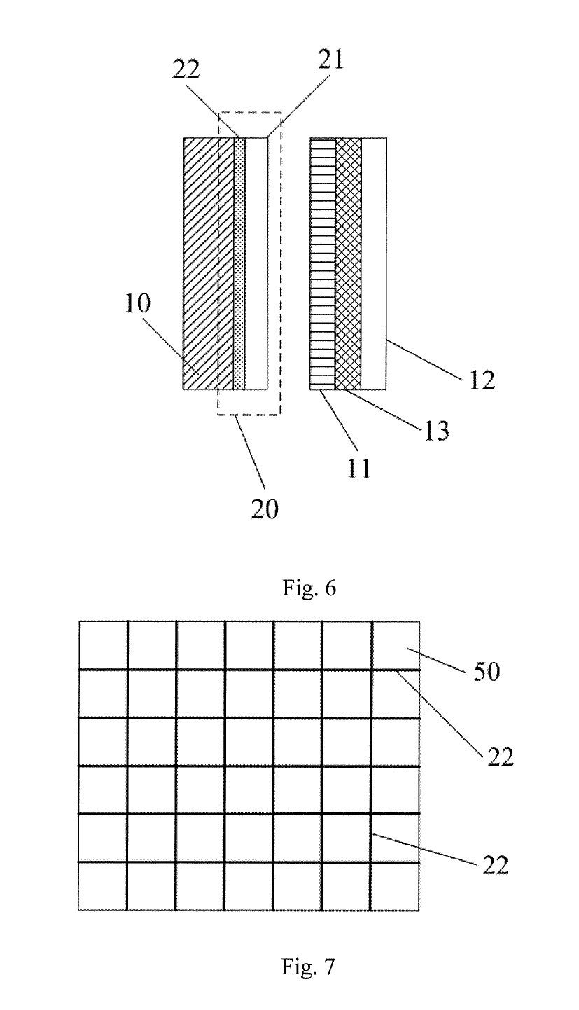

FIG. 5 and FIG. 6 show a touch display device according to the fifth embodiment and the sixth embodiment of the present disclosure respectively. Compared with the touch display device as shown in FIGS. 1-4, in FIG. 5 and FIG. 6, the relative positions of the shielding layer 22 and the substrate 21 in the shielding structure 20 have changed. Specifically, the shielding layer 22 is located on a surface of the substrate 21 facing the display module 10. As shown in FIG. 5, the distance between the shielding layer 22 and the display module 10 may be 0 to 10 mm and can be adjusted between these values based on a variety of factors. As shown in FIG. 6, when the distance between the shielding layer 22 and the display module 10 is 0 mm, the touch display device thus fabricated is thinner. In addition, as shown in FIG. 5 and FIG. 6, the distance between the shielding layer 22 and the touch substrate 12 may be 0.1 to 5 mm. Similarly, the distance between the shielding layer 22 and the touch substrate 12 can be adjusted between these values based on the requirement of actual production.

FIG. 7 shows a the planar structure of the shielding layer 22 in the touch display device according to an exemplary embodiment. As shown in FIG. 7, the shielding layer 22 may be grid-shaped metal lines 22 extending along the horizontal direction and the vertical direction. However, the arrangement of the grid-shaped metal lines 22 may extend along at relative angles other than those expressly shown. Since the grid-shaped metal lines 22 are hollow, the specific thickness of the grid-shaped metal lines 22 is not essential. However, the hollow portion 50 of the grid-shaped metal lines should be arranged to correspond in position with the display area of the display module 10 in the touch display device, and the grid-shaped metal lines 22 are arranged to correspond in position with the non-display area of the display module 10. In addition, in the touch display device according to the embodiment of the present disclosure, the grid-shaped metal lines 22 may also be arranged to correspond in position with the display area and the non-display area of the display module 10, wherein the grid-shaped metal lines 22 arranged to correspond in position with the non-display area are more concentrated than the grid-shaped metal lines arranged to correspond in position with the display area. In such a case, the thickness of the grid-shaped metal lines 22 can be set within a range not influencing the display effect of the touch display device, the specific thickness setting can be determined based on actual production process.

Furthermore, in the touch display device according to the exemplary embodiments, in order to improve transparency of the grid-shaped metal lines 22 and reduce influence of the grid-shaped metal lines 22 on the display effect, the width of the grid-shaped metal lines 22 may be 5 to 100 microns. Further, the spacing between the grid-shaped metal lines 22 may be 0.05 to 10 mm. In actual fabricating process, the width of the grid-shaped metal lines 22 and the spacing between the grid-shaped metal lines 22 can be adjusted appropriately based on the actual extent of electromagnetic interference.

However, in the touch display device according to the embodiment of the present disclosure, the shielding layer 22 may also be a transparent conducting layer. When the shielding layer 22 is a transparent conducting layer, the transparent conducting layer can be an indium tin oxide (ITO) transparent conducting layer, and the ITO transparent conducting layer only needs to be plated on the substrate 21 in the fabricating process. The thickness of the ITO transparent conducting layer plated on the substrate 21 may be 100 Å to 1000 Å.

In addition, when the shielding layer 22 is a transparent conducting layer, the shape of the transparent conducting layer may also be set as a grid shape or a parallel shape, such as etching the ITO transparent conducting layer plated on the substrate 21 into a grid shape or a parallel shape. Since the ITO transparent conducting layer is light transmissive, the display effect of the display module 10 in the touch display device will not be influenced in actual display process. On the other hand, when the shielding layer 22 is a transparent conducting layer, the transparent conducting layer may also be a metal layer, which also only needs to be plated on the substrate 21 directly in the fabricating process, and the metal layer plated on the substrate 21 can also be etched into parallel metal lines. The metal layer should preserve transmission of light after being plated on the substrate 21, such that the display effect of the display module 10 in the touch display device will not be influenced in actual display process. For example, the thickness of the metal layer may be fabricated as 100 Å. The metal layer can be made from commonly used metals, such as molybdenum (MO), chromium (Cr) and nickel (Ni) etc. Besides, the shielding layer 22 in the specific embodiments of the present disclosure may also use other transparent films that can shield electromagnetic interference, while not being limited to the above mentioned ITO transparent conducting layer and metal layer.

Although the present disclosure has been described with reference to specific embodiments, it should be understood that the limitations of the described embodiments are provided merely for purpose of illustration and are not intended to limit the present invention and associated general inventive concepts. Instead, the scope of the present invention is defined by the appended claims, and all variations and equivalents that fall within the range of the claims are intended to be embraced therein. Thus, other embodiments than the specific exemplary ones described herein are equally possible within the scope of these appended claims.

1. A touch display device comprising a display module, a touch substrate and a touch film located on the touch substrate,
wherein the touch display device further comprises a shielding structure located on a first surface of the touch film, wherein the shielding structure is capable of shielding interference from electromagnetic waves to the touch film.

2. The touch display device according to claim 1, wherein the touch substrate is plated with a specular reflection film layer.

3. The touch display device according to claim 2, wherein the specular reflection film layer is a monofilm or a complex film of at least one of: silicon oxide; titanium oxide; and aluminum oxide.

4. The touch display device according to claim 1, wherein the shielding structure comprises a substrate and a shielding layer located on the substrate.

5. The touch display device according to claim 1, wherein the shielding structure is located between the display module and the touch substrate.

6. The touch display device according to claim 5, wherein the shielding structure comprises a transparent substrate and a transparent shielding layer located on the transparent substrate.

7. The touch display device according to claim 6, wherein the distance between the shielding layer and the display module is 0 to 10 mm.

8. The touch display device according to claim 6, wherein the distance between the shielding layer and the touch substrate is 0.1 to 5 mm.

9. The touch display device according to claim 4, wherein the shielding layer is a transparent conducting layer or grid-shaped metal lines.

10. The touch display device according to claim 9, wherein the transparent conducting layer is an ITO transparent conducting layer or a metal layer.

11. The touch display device according to claim 9, wherein the grid-shaped metal lines are arranged to correspond in position with the non-display area of the display module.

12. The touch display device according to claim 9, wherein the grid-shaped metal lines are arranged to correspond in position with the display area and the non-display area of the display module, wherein the grid-shaped metal lines arranged to correspond in position with the non-display area are more concentrated than the grid-shaped metal lines arranged to correspond in position with the display area.

13. The touch display device according to claim 11, wherein the width of each of the grid-shaped metal lines is 5 to 100 microns.

14. The touch display device according to claim 11, wherein the spacing between the grid-shaped metal lines is 0.05 to 10 mm.

15. The touch display device according to claim 5, wherein the electromagnetic waves comprise external electromagnetic waves and electromagnetic waves generated by the display module.
